(19) United States
(12) Patent Application Publication
(10) Pub. No.: US 2013/0271918 A1
(43) Pub. Date: Oct. 17, 2013

(54) COLD PLATE WITH REDUCED BUBBLE EFFECTS

(71) Applicants: JOHN PHILIP NEVILLE HUGHES, MENLO PARK, CA (US); ROBERT J. LIPP, LOS GATOS, CA (US)

(72) Inventors: JOHN PHILIP NEVILLE HUGHES, MENLO PARK, CA (US); ROBERT J. LIPP, LOS GATOS, CA (US)

(21) Appl. No.: 13/448,353

(22) Filed: Apr. 16, 2012

(51) Int. Cl. H05K 7/20; B23P 15/26; F28F 3/12

(52) U.S. Cl. 361/702; 165/169; 29/890.035

(57) ABSTRACT

An electronic system cooling apparatus including a cold plate coupled vertically within an enclosure, the cold plate including a plurality of fluidly isolated, thermally coupled, adjacently nested boustrophedonic channels that terminate in a common upper end and a common lower end. Each turn of each channel includes a top arm and a bottom arm fluidly coupled by a side segment, wherein the top arm is stacked above the bottom arm along the height of the cold plate. An outlet manifold is fluidly coupled to the common upper end of the plurality of channels and an inlet manifold is fluidly coupled to the common lower end the plurality of channels, wherein the inlet manifold is disposed below the outlet manifold to facilitate an upward coolant flow path.

### TECHNICAL FIELD

This invention relates generally to the cooling systems field, and more specifically to a new and useful cold plate in the cooling systems field.

### BACKGROUND

With the onset of high density, high power electronic systems, adequate cooling of the included electronic components is an increasingly significant issue. An electronic system typically includes a plurality of electronic components mounted by conventional means onto bare PC board blades or PC boards. The electronic systems are then mounted into a rack or enclosure. The high density of electronic systems within an enclosure, coupled with each system's high power consumption and subsequently, high heat generation, have rendered conventional air cooling systems inadequate. However, coolant-cooled cold plates offer a suitable solution. These cold plates typically include one or more channels that a coolant is pumped through, wherein the coolant absorbs and transfers the excess heat out of the electronic system. Cold plates using refrigerant have proved highly effective, as they use phase change to absorb heat in an isothermal process.

Unfortunately, conventional cold plates are inadequate for these electronic systems for several reasons. First, in conventional cold plates with manifolds vertically opposed (as shown in FIG. 1B), one of the manifolds becomes an obstruction during insertion of the electronic system into the rack or blade enclosure. Cold plates with horizontally opposed manifolds (shown in FIG. 1A) require extra vertical space, which is at a premium in computer racks. For these reasons, cold plates with single-end feeds are desirable. Secondly, gas bubbles generated during coolant phase change tend to flow upwards and aggregate, forming hot spots on the cold plate where liquid coolant is vacated. This effect is particularly apparent in vertically mounted conventional cold plates with single-end feeds, wherein the flow channels join at a common manifold, opposite the feed end, to facilitate coolant return to the feed end (as shown in FIG. 1B). The upward flow of bubbles also disrupts coolant flow when coolant flow opposes bubble flow (as shown in FIG. 1C), which results in a marked reduction in cooling effectiveness. Thus, there is a need in the cooling systems field to create an improved cold plate.

Presented herein is a method of manufacturing, configuring and deploying a cold plate manufactured from multi-port tubing that is both economical to manufacture and meets the requirements for a refrigerant based system.

### BRIEF DESCRIPTION OF THE FIGURES

FIGS. 1A, 1B and 1C are schematic representations of a first, second and third cold plate of the prior art, respectively.

FIG. 2 is a schematic representation of an embodiment of the cooling system of the invention.

FIGS. 3A and 3B are schematic representations of the enclosure.

FIGS. 4A and 4B are schematic representations of a first and second variation of the cooling system, respectively.

FIG. 5 is a schematic representation of a variation of the channel width relative to the cold plate thickness.

FIGS. 6A and 6B are schematic representations of a first and second cold plate construction, respectively.

FIG. 7 is a schematic representation of the thermal interface.

FIGS. 8A, 8B, 8C, and 8D are schematic representations of a thermal interface pouch, a first, second, and third embodiment of a thermal interface pouch with a plate, and a thermal interface with thermally conductive paste, respectively.

FIGS. 9A, 9B, 9C, and 9D are schematic representations of a first, second, third, and fourth embodiment of the coupling mechanism.

FIG. 10 is a schematic representation of an embodiment of the clip coupling mechanism.

FIG. 11 is a schematic representation of the cooling system including a pumping system.

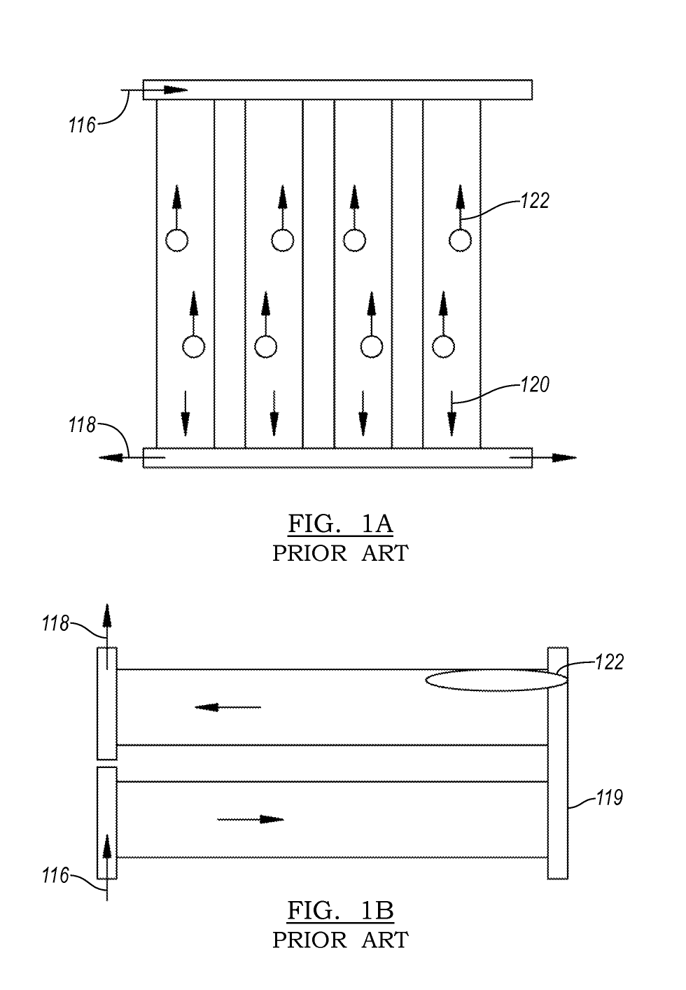

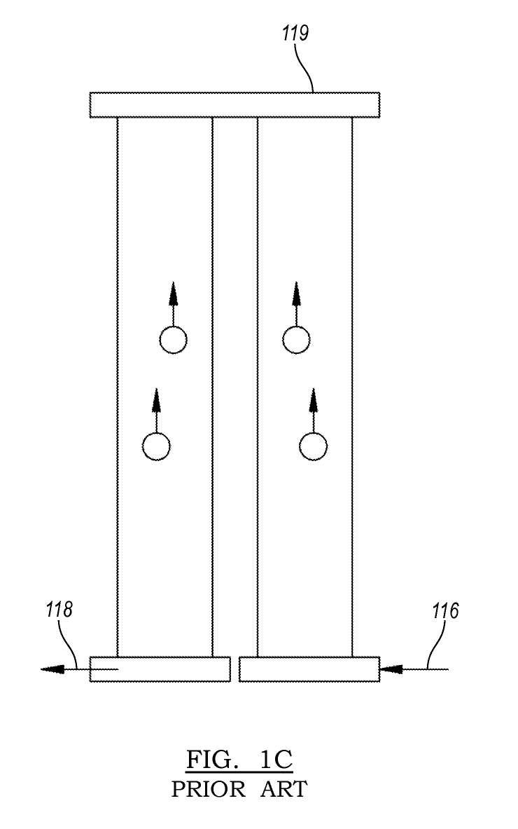

### DESCRIPTION OF THE PREFERRED EMBODIMENTS

The following description of the preferred embodiments of the invention is not intended to limit the invention to these preferred embodiments, but rather to enable any person skilled in the art to make and use this invention.

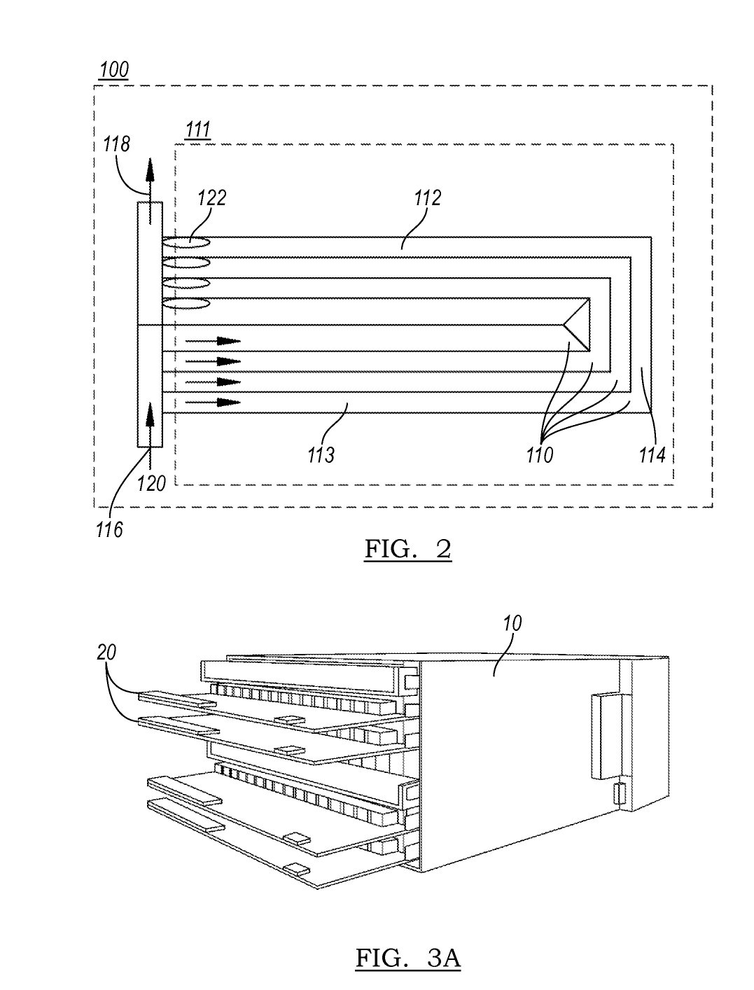

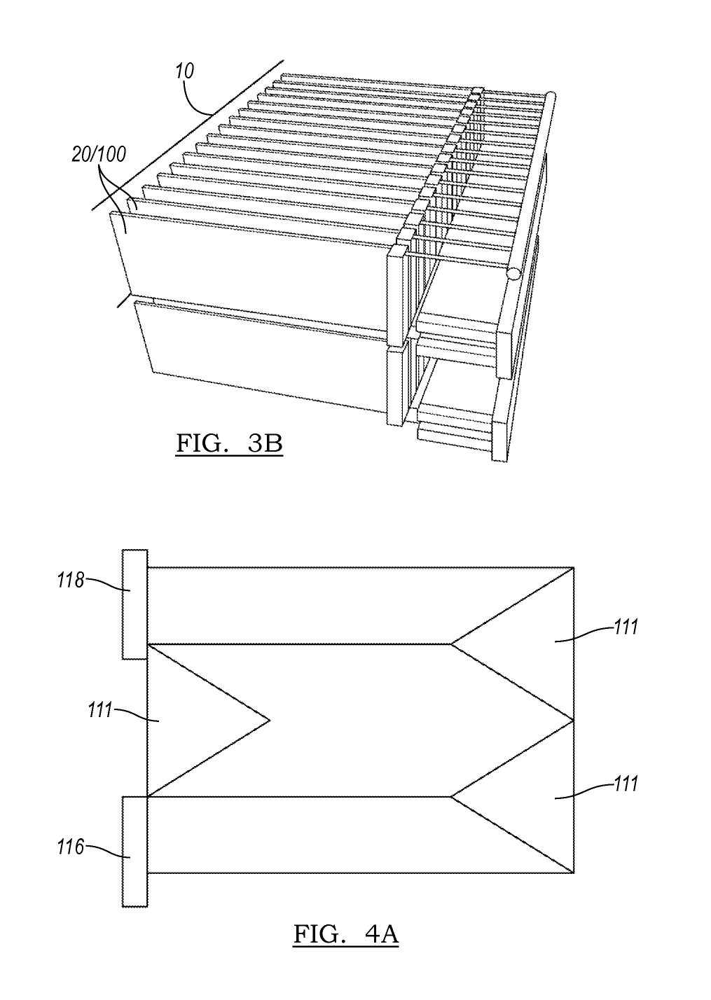

As shown in FIG. 2, the cooling system of the preferred embodiment includes a cold plate 100 with a plurality of fluidly isolated channels no, each channel terminating in a common inlet manifold 116 and a common outlet manifold 118, wherein the inlet manifold 116 is located below the outlet manifold 118. The cooling system is preferably utilized to provide cooling to a plurality of electronic components of an electronic system 20, wherein multiple electronic systems 20 may be mounted proximate to one another, preferably vertically, in an enclosure 10 (as shown in FIGS. 3A and 3B). Multiple enclosures 10 may be mounted in a rack, or the enclosure 10 may encapsulate an entire rack. By fluidly isolating the channels no between the manifolds, the cooling system minimizes bubble aggregation 122, effectively minimizing hot-spot generation. Furthermore, by orienting the inlet manifold 116 below the outlet manifold 118 and pumping coolant 120 upwards, the system achieves a substantially even coolant 120 flow, as the coolant 120 flow direction follows the bubble flow direction. This configuration also allows the cold plate to maintain a thin profile for easy blade insertion. The cooling system may additionally allow higher refrigerant pressures to be used (relative to conventional, flat cold plates) without substantial deformation.

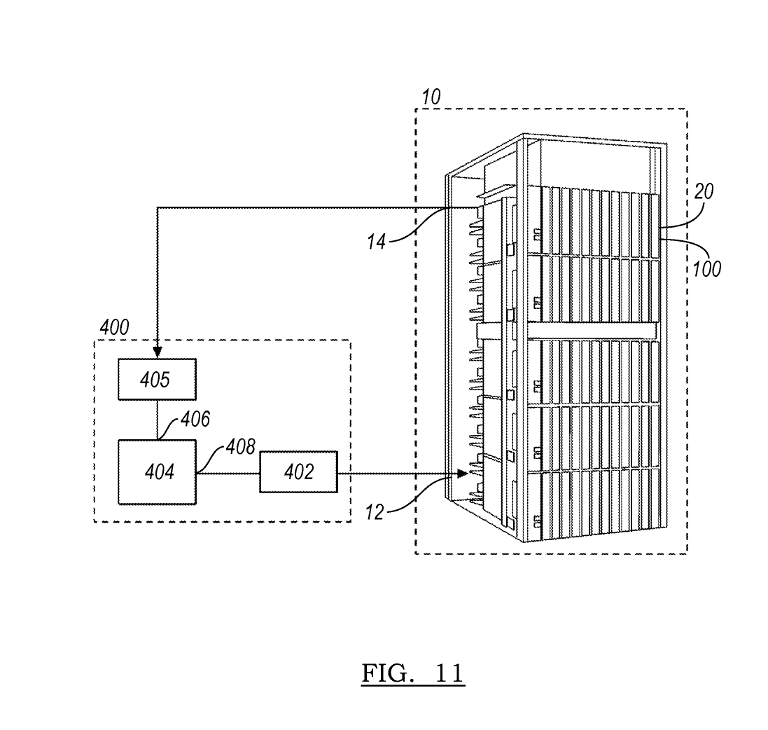

As shown in FIG. 3, the cooling system is preferably utilized with a rack or blade enclosure 10 that functions to support and protect the electronic systems 20 contained within. The enclosure 10 preferably encloses a high density of high power dissipating electronic systems 20, such as servers and switches. These electronic systems 20 preferably incorporate high dissipation components such as CPUs, graphics processing units (GPUs), memory, power supply transistors, inductors, optical transducers, etc. The enclosure 10 preferably supports the electronic systems 20 in a vertical orientation (as shown in FIG. 3B), such that the horizontal footprint of the electronic system 20 in the enclosure 10 is smaller than the vertical footprint. Examples of the enclosure 10 include a blade server and a switch line card. The enclosure 10 may be any size, but is preferably 36″ or narrower in width and smaller than 7′ high and 48″ deep. The rack or blade enclosure 10 preferably also supports a plurality of cold plates 100 in a vertical orientation (as shown in FIG. 3B), and preferably facilitates cold plate 100 to electronic system 20 coupling. Cold plate alignment mechanisms within the enclosure 10 preferably includes grooves or clips that guide and retain the cold plate 100 in position, but may alternately include a tray or any other retention apparatus. The enclosure 10 preferably further includes inlet and outlet coolant connections to the cold plates 100. The enclosure 10 preferably includes one inlet and outlet connection for a subset of the supported cold plates 100, or a single inlet and outlet connection for the plurality of cold plates 100 within the enclosure 10. The latter embodiments may include one or more mainlines with branching pipes to feed and drain the cooling plates. The enclosure 10 preferably additionally includes a coolant inlet 12 and a coolant outlet 14 (as shown in FIG. 11) through which coolant 120 is pumped, but may alternatively not include a coolant inlet 12 or outlet 14.

### 1. The Cold Plate.

As shown in FIG. 2, the cold plate 100 of the cooling system functions to transfer heat from the internal components of electronic systems 20 to a coolant 120 flowing inside the cold plate 100. The cold plate 100 cools the electronic systems 20 more effectively than prior art cold plates 100 by fluidly isolating each coolant channel 110 to minimize hot spot generation, and by utilizing an upward coolant flow pattern to minimize bubble flow effects. The coolant channels 110 within the cold plate 100 are preferably thermally coupled, such that localized heat applied to one channel 110 is dissipated through the channels adjacent to the heated channel.

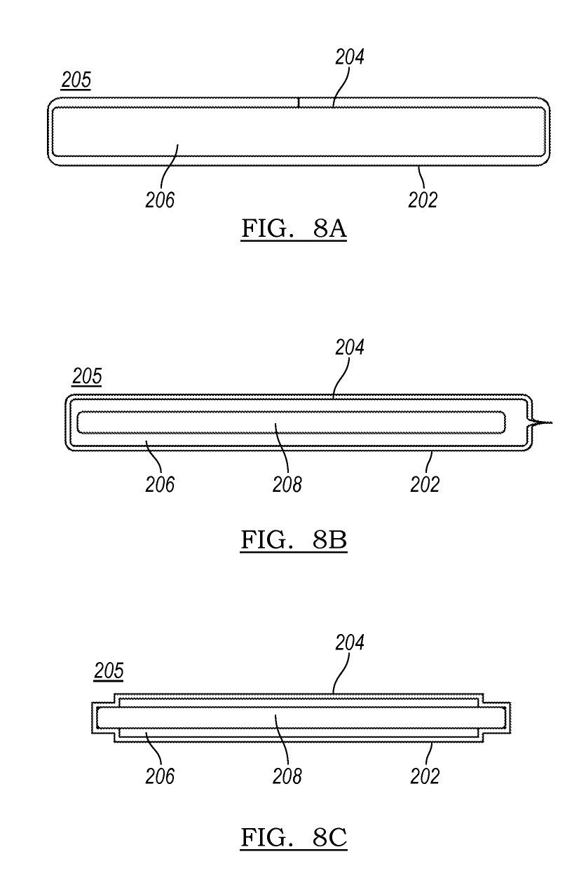

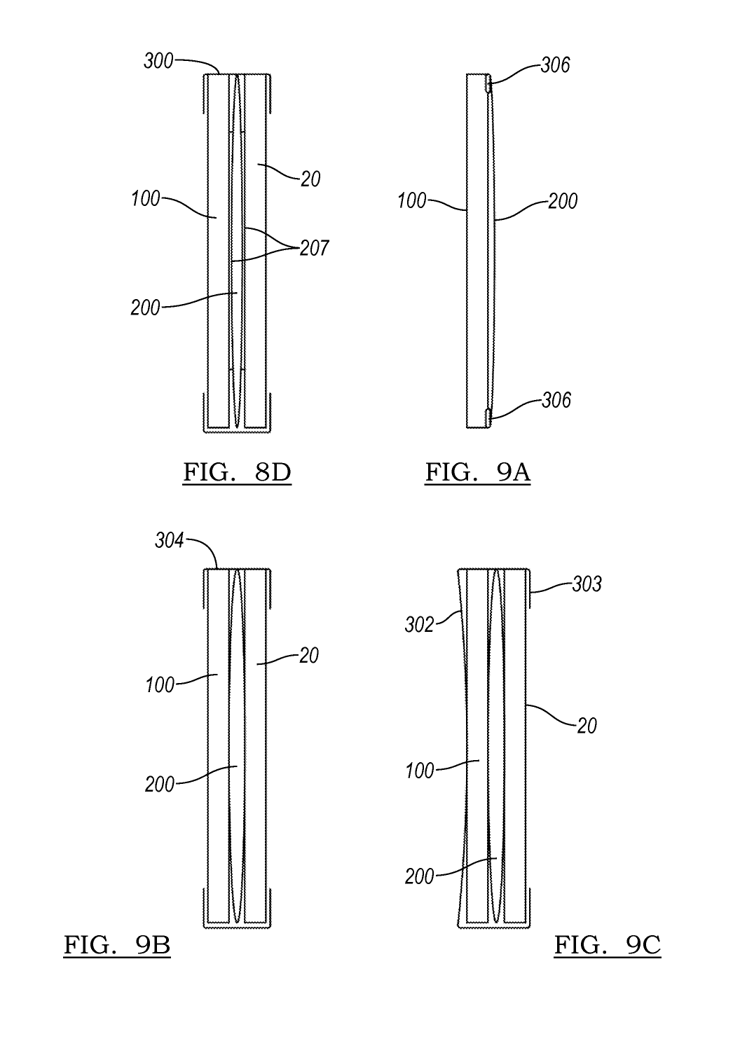

The cold plate 100 preferably directly couples to an electronic system 20 to remove heat, but may alternately indirectly couple to the system 20 and/or an electronic component of the system 20 through a thermal interface 200 (as shown in FIG. 8D), or through air, wherein the cold plate cools the air of the electronic system 20 and thereby components within. The cooling system may additionally include a thermal interface 200, which functions to increase thermal coupling between the electronic system 20 and its components and the cold plate 100.

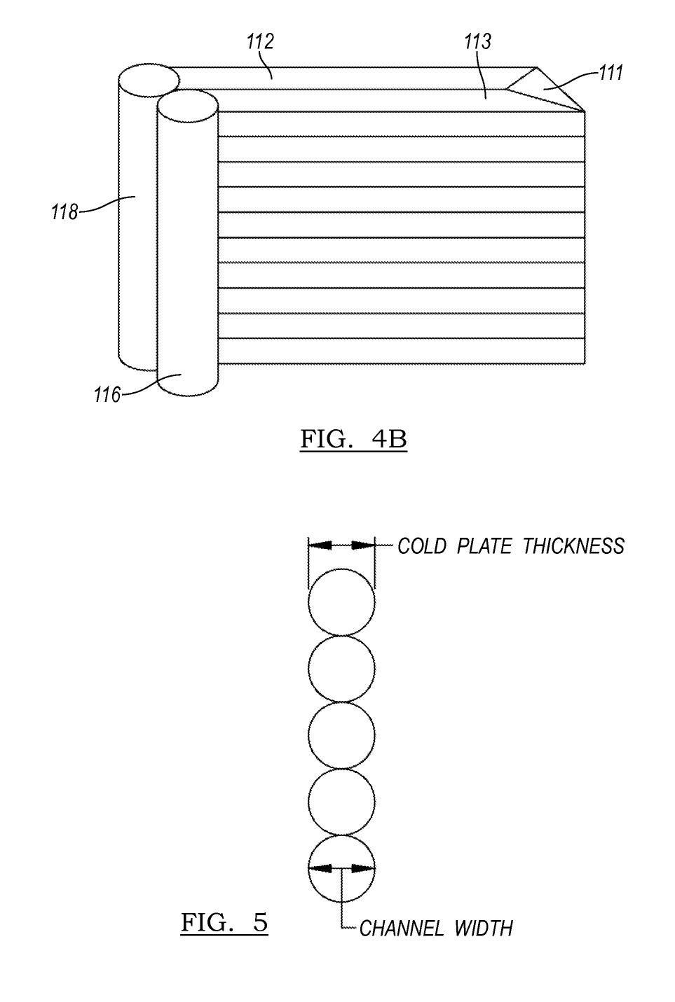

The cold plate 100 preferably includes a plurality of substantially parallel, fluidly isolated coolant channels no that terminate in a common inlet manifold 116 and a common outlet manifold 118. The channels no are preferably mechanically and thermally coupled together and form a substantially planar structure. To facilitate upward coolant 120 flow, the inlet manifold 116 is preferably disposed under the outlet manifold 118. More preferably, the inlet manifold 116 and outlet manifold 118 are located on the same side of the cold plate 100, wherein the inlet manifold 116 is located directly beneath the outlet manifold 118. The ingress port of inlet manifold 116 preferably has a built-in flow restriction in order to control the flow of coolant through the cold plate, thus ensuring even distribution of coolant to all the cold plates on a single cooling circuit. The flow restriction is preferably a small orifice in the wall of the inlet manifold that restricts the coolant flow to the desired rate for the coolant pressures provided by the attached cooling pump. In a preferred embodiment, a 0.045″ diameter orifice is used. However, the ingress port may alternatively include any size orifice, any suitable flow restriction, or no flow restriction at all. The coolant channels 110 are preferably serpentine or boustrophedonic, wherein each turn 111 of the channel no includes a top arm 112, a bottom arm 113, and a side segment 114 that fluidly couples the top 112 and bottom arms 113. The arms of the channels no are preferably horizontal, and stack along the height of the cold plate 100 in a plane. However, the arms may lie adjacent each other within the enclosure, such that the cold plate thickness is substantially twice the thickness of the channels no (e.g. the outlet channels are folded against the inlet channels), as shown in FIG. 4B. The side segment 114 is preferably vertical, straight, and forms a right angle with both the top arm 112 and bottom arm 113, but may alternately be curved and form a U-shaped curve with the top arm 112 and bottom arm 113, which also may be curved to accommodate the cold plate configuration (e.g. have a crescent shape). The channels no preferably include a single turn 111, with a single top arm 112, a single bottom arm 113, and a single side segment 114, but may alternately include 1.5 turns (e.g. a turn 111 with an additional side segment 114 and top arm 112), three turns 111 (as shown in FIG. 4A), or any suitable number of turns 111. The channels no preferably nest adjacently, with an inner channel 110 and an outer channel 110 for each turn 111, wherein the inner channel no has a tighter turn 111 radius than the outer channel no. The channels no preferably have the same cross sectional areas, but may alternately have different cross sectional areas. The channel no cross sectional areas are preferably small enough such that “dry” areas (areas without liquid coolant) formed within a channel no by bubble formation and aggregation are limited in size, such that the thermal conductivity of the cold plate material is sufficient to eliminate any potential hot spot by conducting the heat from the “dry” area to an area with liquid coolant elsewhere within the cold plate. The channels 110 preferably have a width substantially the thickness of the cold plate 100 (as shown in FIG. 5), but may alternately have a width smaller than the thickness of the cold plate 100, wherein the channels 110 are biased toward a broad face or located in the center of the cold plate thickness. The cold plate 100 is preferably prismatic and couples to electronic system 20 along a broad face, but may be any suitable shape to accommodate the electronic system 20. The cold plate is preferably made of copper, aluminum, steel, or metal-embedded polymer resin, but may alternatively be made of any suitable thermally conductive material.

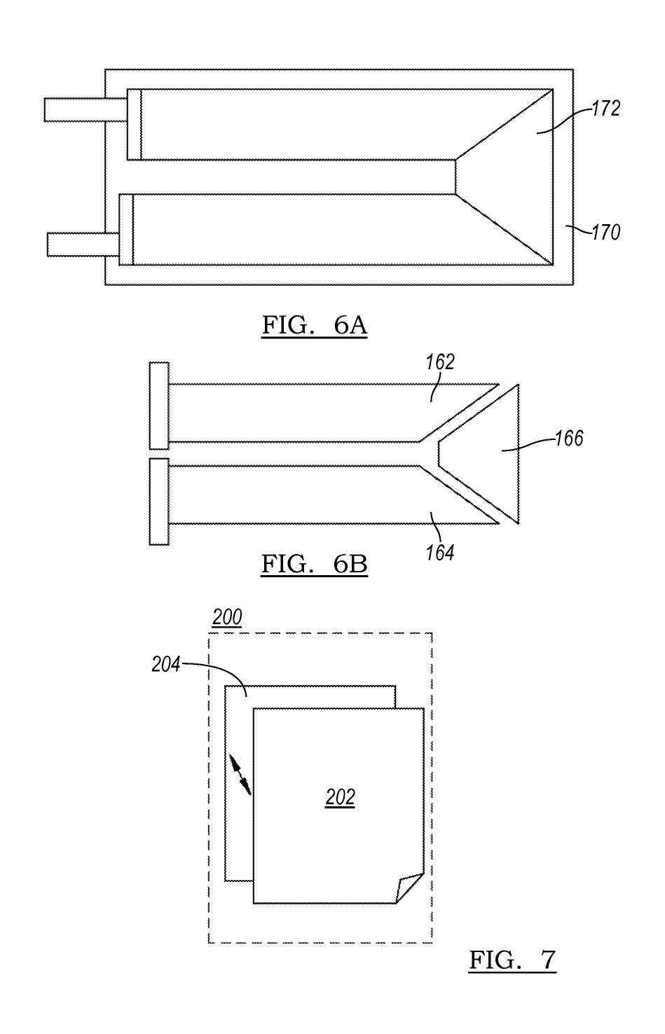

As shown in FIG. 6A, the cold plate 100 is preferably manufactured by carving the channels no into the surface of a plate 170 as grooves 172, then sealing the grooves 172 with a second plate (e.g. a cover plate) to form channels 110. The grooves 172 may be carved into the plate by machining, etching, stamping, forging, or through any suitable method of forming or removing material from the plate surface. The grooves 172 may be sealed by brazing, soldering, adhering (e.g. with glue or epoxy), or utilize any other method of fluidly sealing the second plate onto the first plate.

Alternatively, as shown in FIG. 6B, the cold plate 100 may be manufactured in sections. The top arm 112 of the cold plate 100 is preferably manufactured from a first piece 162, the bottom arm 113 of the cold plate 100 is preferably manufactured from a second piece 164, and the side section 114 of the cold plate 100 is preferably manufactured from a third piece 166. The channels no of the first and second pieces (162 and 164, respectively) preferably terminate in one straight end and one angled end, whereas the channels no of the third piece 166 preferably terminate in two ends angled toward each other. The angled ends of the three pieces are then joined by brazing, soldering, adhering, laser welding, e-beam welding, or any suitable method of forming a fluid seal, wherein the straight ends of the first and second pieces (162 and 164, respectively) are joined to an inlet 116 and outlet manifold 118. This construction is preferably used to manufacture the cold plate embodiment with a single turn 111, but may be used to manufacture other cold plate embodiments as well. The first, second, and third pieces 162, 164, and 166 are preferably manufactured from nickel-plated, multi-port aluminum tubing, but may alternatively be manufactured from individual tubes or from any other suitable material and/or construction. In a first preferred embodiment of the method of manufacturing this cold plate embodiment, the first, second, and third pieces (162, 164, and 166, respectively) are formed from butt brazing, welding, or soldering together a plurality of coolant tubes with nickel alloy, aluminum, aluminum-silicon, copper alloy, gold-silver, or any suitable material. In a first variation, the individual tubes that form the coolant channels are pre-cut, then joined together. In a second variation, the tubes are joined together, then cut to form pieces 112, 113, and 114. The first, second, and third pieces (112, 113, 114, respectively) are then clamped in a jig in the configuration shown in FIG. 6B. Lead-free solder paste is applied along the join lines, along the top and bottom of the cold plate. The whole is then heated until the solder paste melts and flows into the joint, forming a substantially gas tight seal. Alternatively, the join lines may be covered with a tape including a layer of flux-covered solder foil and a layer of metal foil, wherein the metal foil has a higher melting point than the solder foil, such that the solder foil may adhere to the metal foil. The tape is applied such that the solder side is in contact with the tubes. The whole is then heated until the solder melts and flows into the joint. This method may be advantageous in that it allows just sufficient solder flow into the joint to form an effective seal, but not so much solder as to block any of the tubes. Alternatively, the pieces may be joined along the join lines by brazing, welding (e.g. laser, e-beam, arc, friction, etc.), or any other joining method. The manifolds are then slipped onto the free ends of the first and second piece (162 and 164) and soldered into position. All components may be “pretinned” by dipping in solder prior to assembly to assure complete solder flow over all joined surfaces. However, the cold plate may be manufactured utilizing any other suitable manufacturing process.

The cold plate 100 may also be manufactured channel by channel, wherein a tube is bent to the desired radius to form the channel, then coupled to a second tube or manifold. The tubes may also be formed by first cutting an angled wedge, transverse the tube longitudinal axis, through a portion of the tube diameter, then bending the tube toward the wedge. The wedge is preferably a 45° wedge, such that the bent tube forms a right angle, but may alternately be a wedge with any other angle. The tubes are then welded, brazed, or otherwise joined together in the desired pattern. These multiple individual tubes preferably each traverse the full distance from inlet manifold 116 to outlet manifold 118, either through a single turn or through multiple turns. These tubes may be coupled together mechanically, thermally or both, by welding, brazing or any other suitable coupling means. The resulting structure may be further planarized by mechanical pressure or by filling voids between tubes with additional material such as solder or braze. Alternatively, the tubes may be affixed to a second surface such as a flat metal sheet that mechanically and thermally couples and planarizes the tubes, or has a different shape that conforms to the electronic system 20.

The surface of the cold plate 100 that couples to the thermal interface 200 is preferably smooth, but may alternatively be grooved, embossed or otherwise textured to enhance thermal coupling with the thermal interface. This textured surface of the cold preferably includes multiple raised surfaces (e.g. bumps), locally increasing the surface area between the cold plate and the thermal interface, and locally reducing the thickness of thermal fluid 206 where it is pushed aside by the raised portions of the textured surface.

The coolant 120 within the cold plate 100 is preferably refrigerant (e.g. ammonia, carbon dioxide, halogenated or non-halogenated hydrocarbons or any other suitable liquid to gas phase change material), but may alternately be water or any other fluid. The heat carrying capacity of the fluid flow through the cold plate is preferably in excess of the total heat load applied to the cold plate to avoid overheating the electronic components.

### 2. The Thermal Interface.

The cooling system may additionally include a thermal interface 200, which functions to increase thermal coupling between the electronic component 20 and the cold plate 100. As shown in FIG. 7, the thermal interface 200 preferably includes a compliant strength layer 202 that functions to resist tear, a compliant conductive layer 204 that functions to reduce the overall thermal impedance and spread heat from the strength layer 202, and a thermally conductive fluid 206 that functions to increase the heat flux from the conductive layer to the cold plate 100. The thermal interface 200 is preferably laminated, but may be otherwise joined. In another variation, the thermal interface 200 may alternatively be a substantially conductive material such as stainless steel, copper, or any other suitable thermal interface, and can be a plate, foil, or have any other suitable thickness. The conductive layer may additionally function to form a hermetic seal to enhance encapsulation of the conductive fluid, The thermal interface 200 is preferably coupled to the cold plate during installation, wherein a substantially normal force, applied by the cold plate 100 to the thermal interface 200, preferably retains the thermal interface position relative to the cold plate 100 and electronic system 20. However, the thermal interface 200 may be retained against the cold plate 100 by a retention mechanism (e.g. clips, adherent, etc.), wherein the thermal interface 200 is preferably retained along its edges (e.g. with the thermally conductive fluid 206 disposed between the thermal interface 200 and the cold plate 100) or substantially along a broad face.

The thermally conductive fluid 206 is preferably disposed between the conductive layer 204 and the cold plate 100, such that heat is transferred through the strength layer 202 to the conductive layer 204, and distributed to a larger area of the cold plate 100 through the thermally conductive fluid 206. The thermally conductive fluid 206 is preferably thixotropic, inert and electrically insular, and is preferably a ceramic or metal-based thermal grease (e.g. silicone oil with boron nitride, aluminum oxide, metallic silver or aluminum particles, etc.), but may be any suitable thermally conductive fluid 206. The strength layer 202 preferably includes a polyester such as PET, but may alternately include another wear-resistant material. The conductive layer 204 preferably includes aluminum, but may alternately include copper or any other conductive material. Both the strength 202 and conductive 204 layers are preferably thin sheets. For example, a thermal interface 200 may include a 0.0005″ polyester strength layer 202 and a 0.002″ aluminum conductive layer 204. The strength 202 and conductive 204 layers are preferably joined together along their broad faces to form a single sheet, and are preferably joined by adhesive. Alternatively, the strength and conductive layers may be joined along the edges, quilted, or joined in any suitable location. The layers are preferably adhered together, but may be stitched, laminated, fastened, or utilize any other joining mechanism. As shown in FIG. 8A, the edges of the sheet may additionally be joined to form a sealed pouch 205, wherein the pouch 205 is filled with a thermally conductive fluid 206. The thermal interface 200 is preferably arranged with the strength layer 202 on the exterior, such that the conductive layer is sandwiched between the strength layer 202 and the thermally conductive fluid 206. However, the thermal interface 200 may alternatively be arranged with the conductive layer 202 on the exterior, with alternating layers of conductive and strength layers 202 and 204, or be configured in any other suitable arrangement.

As shown in FIG. 8B, the thermal interface 200 may additionally include a conductive plate 208 encapsulated within the pouch 205 that functions to increase and evenly distribute heat throughout the pouch 205, as well as provide structural support to the thermal interface 200, creating a self-supporting thermal interface plate. Heat is preferably transferred through the strength layer 202 to the conductive layer 204, distributed to the thermally conductive fluid 206, transferred to the conductive plate 208, and transferred to the cold plate 100, either directly or though additional conductive fluid 206, layers of conductive 204 and strength 202 layers. As shown in FIG. 8C, the conductive plate 208 is preferably coupled to the pouch 205 along opposing edges, but may alternately be uncoupled to the pouch 205, as shown in FIG. 8B. Alternatively, a simple grease or conventional thermally conductive interface pad may be used to thermally couple the cold plate 100 to the conductive plate 208. In the latter case, layers 202, 204 are preferably attached to conductive plate 206 on only one side, as shown in FIG. 8D. Layers 202 and 204 are preferably stretched tightly onto or around plate 208 to prevent slumping of the fluid 206 to the bottom of the thermal interface plate when mounted on edge. Use of a high viscosity or thixotropic thermal grease is also preferable to prevent slumping. The conductive plate 208 preferably includes metal, but may alternately include a thermally conductive polymer, graphite, or any suitable material. The conductive plate 208 is preferably thicker than the strength 202 and conductive 204 layers; for example, the plate may be 0.03″ in the polyester-aluminum thermal interface embodiment. Furthermore, the pouch 205 preferably includes an adequate amount of thermally conductive fluid 206 to substantially coat the surface of the conductive plate 208. In one embodiment, approximately 0.02″ of thermally conductive fluid 206 is disposed between each broad face of the conductive plate 208 and the conductive layer 204. As shown in FIG. 7E, the thermal interface 200 may also include a layer of thermally conductive grease 207 on the electronic system 20, its components and/or cold plate 100 interface. The thermal interface 200 may additionally include an EMI shielding layer, such that the thermal interface 200 may be used as a lid, or may include additional strength layers 202, such as a porous fiberglass layer through which thermally conductive fluid 206 can flow.

The thermal interface 200 is preferably large enough to couple to substantially the entire broad face of an electronic component, and is more preferably large enough to substantially couple to the entire broad face of the cold plate 100 and at least one electronic system 20. Alternatively, the thermal interface 200 may be large enough to couple to an entire broad face of the lid of the electronic system 20. Furthermore, the thermal interface 200 preferably includes enough thermally conductive fluid 206 such that substantial voids do not form during use.

### 3. The Coupling Mechanism.

The cooling system preferably additionally includes a coupling mechanism 300 that couples the thermal interface 200 and/or electronic system 20 to the cold plate 100. The coupling mechanism 300 may further couple the cold plate-thermal interface system to an electronic system 20.

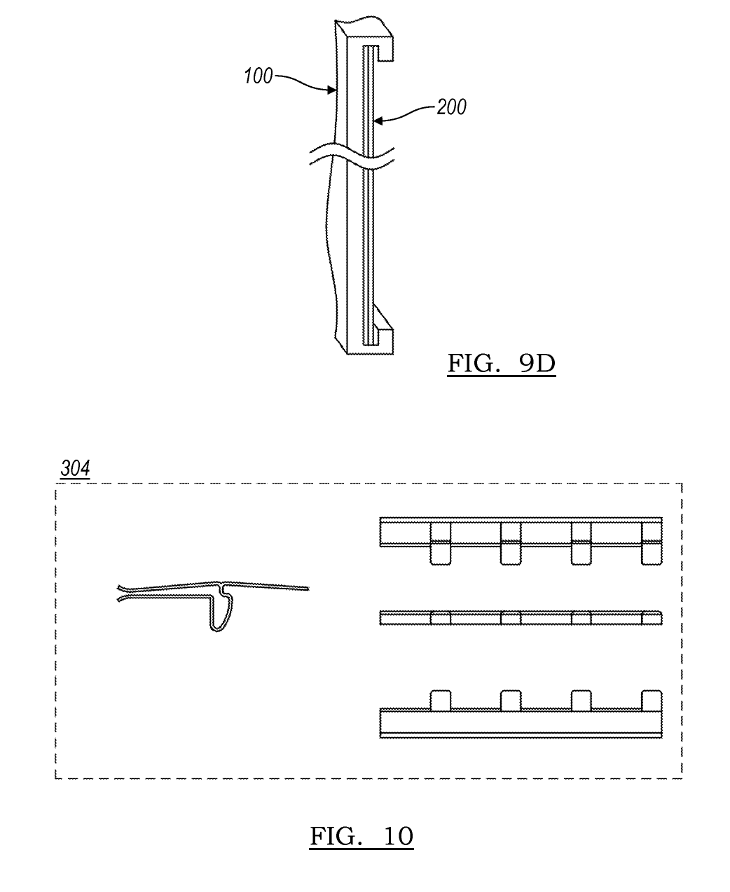

In a first embodiment, as shown in FIG. 9A, the coupling mechanism 300 includes an adherent, wherein the thermal interface 200 is adhered to the broad face of the cold plate 100 with adhesive 306. A substantial surface of the thermal interface 200 may be adhered to the cold plate 100, but the thermal interface 200 may alternately adhere to the cold plate 100 only along the edges. The thermal interface 200 preferably retains substantially full contact with the cold plate 100 along a broad face. However, in the pouch thermal interface embodiment, substantially half of the pouch 205 surface is preferably coupled to the cold plate 100. In the sheet thermal interface 200 embodiment, the edges of the sheet are preferably adhered to the edges of the cold plate 100 with the conductive layer 204 proximal the cold plate 100, wherein the resultant cavity is preferably filled with thermally conductive fluid 206. The adhesive 306 may be any suitable adherent, such as conductive epoxy, metal tape, or Velcro. A second coupling mechanism may then compress the cold-plate/thermal-interface structure against the electronic system 20.

In a second embodiment of the coupling mechanism 300, as shown in FIG. 9B, the thermal interface 200 and/or electronic system 20 may be clipped to the cold plate 100, wherein a clip 304 (as shown in FIG. 10) or functionally similar structure is slid over the edges of the cold plate 100 and thermal interface 200 and/or electronic system 20. The clip 304 may simply provide support for the thermal interface 200 that maintains the cold plate 100, thermal interface 200 and electronic system 20 it in a proximate position, or may apply a substantially normal, compressive force to the edges of the systems to compress the thermal interface 200, electrical system 20, and cold plate 100 together. The clip 304, if used as a compressive mechanism, preferably retains some shape memory, and is preferably metal (e.g. aluminum, steel, copper, etc), but may alternately be polymeric. If not used as a compressive mechanism, the system may additionally include a second coupling mechanism 300 that provides a compressive force to the edges of the electronic system 20 and thermal interface 200.

In a third embodiment of the coupling mechanism 300, as shown in FIG. 9C, a pressure plate 302 compresses the cold plate 100 against the thermal interface 200 and/or electronic system 20. The pressure plate 302 is preferably integrated into the enclosure 10, but may alternately be a separate piece. The pressure plate 302 preferably applies a substantially normal, compressive force to compress the broad face of the cold plate 100 against the electronic system 20, but may alternately apply a normal, compressive force to only the edges of the cold plate 100. The broad face of the pressure plate 302 is preferably substantially the same size as the broad face of the cold plate 100, but may be much smaller, covering only a portion of the cold plate 100. The pressure plate is preferably made of a shape-memory material and is somewhat compliant, such that pressure plate 302 flexion results in a reactive spring force against the face of the cold plate 100. The pressure plate is preferably movable relative to the cold plate 100 (more preferably, moveable within the electronic system 20), such that the pressure plate may be moved against the cold plate 100 after the electronic system 20 is installed within the enclosure 10. The pressure plate 302 is preferably made of metal (e.g. copper, aluminum, steel, etc), but may alternately be made of polymer. The pressure plate may be an independent structure, or may be integrated into a multi-functional structure (e.g. as the lid of an electronic system 20, as a component of the enclosure 10, etc.).

The pressure plate may additionally include a compliance layer between the pressure plate and cold plate to compensate for mechanical tolerances and other variances in the distance and planarity of the cold plate 100 with respect to the electronic system 20 in the coupled and uncoupled states. The compliance layer is preferably a foam tape that is coupled to a broad face of the cold plate distal from the electronic system, but may alternatively be a rubber pad or any other suitable layer that distributes the force applied by the pressure plate over the cold plate. The foam tape is preferable 0.62″ thick before compression. The compliance layer is preferably attached to the cold plate with a pressure sensitive adhesive, but may alternatively be glued, screwed, restrained by friction, or otherwise retained between the cold plate and pressure plate, and may be coupled to a broad face of the cold plate broad or the pressure plate. The compliance layer may cover the entire the cold-plate/pressure plate-interface, or may cover a portion of the interface, depending on the pressure-compression ratio desired. The compliance layer may be a composite. For example, the compliance layer may include foam tape along the cold plate-coupling face and a material with a low coefficient of friction, such as PTFE or acetal on the pressure plate-coupling face, which may provide both mechanical protection for the tape and reduced operational forces when sliding the pressure plate across the cold plate surface.

In a fourth embodiment, as shown in FIG. 9D, the coupling mechanism 300 includes a grooved structure that retains the cold plate 100 against the thermal interface 200. This grooved structure is preferably an integral part of the cold plate, but may alternatively be a separate piece affixed thereto. Alternatively, the grooved structure may be affixed to the thermal interface plate and slipped over the cold plate, or simply a separate piece, wherein both the cold plate 100 and the thermal interface 200 slide into and are retained by the grooved piece. Any combination of the aforementioned coupling mechanisms 300 may be utilized to couple the cold plate 100 to the thermal interface 200, and the thermal interface 200 to the electronic system 20.

As shown in FIG. 11, the system may additionally include a pumping system 400 that functions to pump coolant 120 into and out of the system. The pumping system 400 preferably includes a heat exchanger 405, coolant reservoir 404, a pump 402, an inlet 406 and an outlet 408. The pumping system 400 preferably manages the cold plates 100 of one enclosure 10, but may alternately manage the cold plates 100 of multiple enclosures 10, wherein the pumping system 400 includes multiple inlets 406 and outlets 408. The pumping system 400 is preferably incorporated within the enclosure 10, but may alternately include select systems within the enclosure 10 or be entirely separate from the enclosure 10. The coolant reservoir 404 of the pumping system 400 functions to hold coolant 120 to be pumped into the cold plates 100 and is preferably fluidly coupled to the outlet 408. The coolant reservoir 404 preferably holds fresh liquid coolant 120, but may hold heated coolant 120 in gaseous or liquid form. The pumping system 400 preferably includes one coolant reservoir 404, but may include multiple coolant reservoirs 404 that either cool multiple enclosures 10 and/or cold plates 100, or segregates heated coolant 120 from unheated coolant 120. The pump 402 of the pumping system 400 functions to pump 402 coolant 120 from the coolant reservoir 404, out the outlet 408, to the cold plates 100, through the heat exchanger 405, and back to the reservoir 404 through the inlet 406. The pump 402 is preferably a positive displacement pump 402 (e.g. rotary pump, reciprocating pump, peristaltic pump, etc), but may alternately be an impulse pump, velocity pump, centrifugal pump, or any suitable pump. The inlet 406 of the pump 402 system functions to facilitate coolant 120 ingress into the pump 402 system, and is preferably fluidly coupled to the coolant reservoir 404 and enclosure 10 or cold plate outlet (14 and 118, respectively) during use. The outlet 408 of the pumping system 400 functions to facilitate coolant 120 egress from the pumping system 400, and is preferably fluidly coupled to the coolant reservoir 404 and the enclosure or cold plate inlet (12 and 116, respectively) during use.

In a first preferred embodiment, the cooling system includes a cold plate 100, a thermal interface 200, and a coupling mechanism 300. The cold plate 100 includes a plurality of fluidly isolated, thermally coupled channels 110 formed into one turn 111, wherein each channel 110 includes one horizontal top arm 112 and one horizontal bottom arm 113 fluidly coupled by a vertical side section 114. The top arm 112 is fluidly coupled to an outlet manifold 118, the bottom arm 113 is fluidly coupled to an inlet manifold 116, and the outlet manifold 118 is located above the inlet manifold 116 on the same side of the cold plate 100. The thermal interface 200 includes a pouch 205 made of a thin polyester sheet 202 laminated to a thin aluminum sheet 204 that encloses a metal plate 208 encapsulated by thermal grease 206. The coupling mechanism 300 includes slotted structures that mechanically support and align the thermal interface in proximity to the cold plate.

A second preferred embodiment of the cooling system includes a cold plate 100, a thermal interface 200, and a coupling mechanism 300. The cold plate 100 is substantially the same as in the first embodiment. The thermal interface 200 is also substantially the same as the first embodiment, without the enclosed metal plate 208. The coupling mechanism 300 of the second embodiment includes a pressure plate 302 that couples the cold plate 100 to the electronic system 20, sandwiching the thermal interface 200 in between. The pressure plate 302 includes a plate substantially the size of the cold plate 100 broad face and a brace 303, wherein the plate 302 is disposed on the side of the cold plate 100 distal to the electronic system 20, and the brace 303 is disposed on the side of the electronic system 20 distal to the cold plate 100. The pressure plate 302 includes a lever that forces the plate 308 toward the brace 303 when activated, compressing the cold plate 100 and thermal interface 200 against the electronic system 20.

### 4. Methods of Use.

The cooling system is configured to be easily installed within a rack or enclosure 10 by a technician.

In a first embodiment of the method of use, the cooling system includes a pressure plate and a cold plate, wherein the cold plate further includes a thermal interface, and is used to cool an electronic system 20 within an enclosure 10.

A cold plate 100 is slid partially into the enclosure 10. An electronic system 20 is then mounted, proximal to the cold plate 100, into the enclosure/rack 10 (e.g. by sliding the electronic system into grooves within the rack). The electronic system couples to the cold plate as the electronic system slides into the enclosure, simultaneously mounting the cold plate within the enclosure and aligning the cold plate against the electronic system. The electronic system may couple to the cold plate by accepting the cold plate edges within an integrated groove/slot on the electronic system; the broad face of the electronic system may couple to the cold plate broad face, wherein friction causes the electronic system and cold plate to slide together along parallel tracks within the electronic enclosure; may be pre-coupled to the cold plate; or be coupled and/or aligned utilizing any other suitable mechanism. The cold plate is preferably aligned such that the thermal interface is proximal to the electronic system 20. The pressure plate is preferably then aligned with the cold plate and compressed against the broad face of the cold plate distal the electronic system 20, such that the cold plate and thermal interface is forced against the electronic system 20 and/or its components. The pressure plate is preferably the lid of the electronic system 20, but may alternatively be a separate component, a movable component within the enclosure 10, or any suitable pressure plate. The pressure plate is preferably retained in an uncoupled position relative to the cold plate (e.g. not compressing the cold plate) by a clip, but may alternatively utilize any suitable position retention mechanism. The pressure plate preferably slides along grooves within the electronic system 20 to move into a coupled position (e.g. compressing the cold plate), wherein the coupled position effectively seals the electronic system 20 and compresses the cold plate against the electronic system 20 and/or its components. In other words, the grooves preferably guide the pressure plate in an inwards direction, toward the interior of the electronic system 20, as the pressure plate slides along the length or width of the electronic system 20. The pressure plate is preferably slid in a direction substantially parallel to the broad face of the electronic system 20 (i.e. along the electronic system width or length), but may alternatively be slid in a direction substantially normal to the broad face of the electronic system 20. The electronic system 20 is preferably inserted into the enclosure 10 such that the technician pulls the edge of the pressure plate to seal the electronic system 20, but may alternatively be inserted into the enclosure in any other suitable orientation.

However, any other suitable method of installing the cooling system and electronic system 20 may be utilized.

As a person skilled in the art will recognize from the previous detailed description and from the figures and claims, modifications and changes can be made to the preferred embodiments of the invention without departing from the scope of this invention defined in the following claims.

We claim:

1. A cooling system for an electronic system, the cooling system comprising:
an enclosure;
a cold plate with a thickness, a height, and a length, configured to be vertically coupled against the enclosure, the cold plate comprising:
a plurality of fluidly isolated, thermally coupled, adjacently nested boustrophedonic channels terminating in a common upper end and a common lower end, wherein each turn of each channel includes a top arm and a bottom arm fluidly coupled by a side segment, wherein the top arm is stacked above the bottom arm along the height of the cold plate;
an outlet manifold fluidly coupled to the common upper end of the plurality of channels; and,
an inlet manifold fluidly coupled to the common lower end of the plurality of channels, wherein the inlet manifold is disposed below the outlet manifold;
wherein the channels encapsulate a coolant; and,
a thermal interface, coupled to the cold plate, the thermal interface comprising a thin metallic layer, wherein the thermal interface is coupled to the cold plate and forms a cavity, wherein the cavity contains a thermally conductive fluid.

2. The system of claim 1, wherein the inlet manifold is adjacent the outlet manifold.

3. The system of claim 1, wherein the channels comprise a single turn, such that the channels include one top arm, one bottom arm, and one side segment.

4. The system of claim 1, wherein the side segment is straight and forms a right angle with the top arm and bottom arm of each channel.

5. The system of claim 1, wherein the side segment is curved and joins with the top and bottom arms of each channel to form a U-shaped turn.

6. The system of claim 1, wherein the coolant is refrigerant.

7. The system of claim 1, wherein the edges of the thermal interface are joined together to form a pouch enclosing the cavity.

8. The system of claim 7, wherein the pouch is substantially coupled to an entire broad face of the cold plate.

9. The system of claim 7, wherein the pouch further encapsulates a metal plate.

10. The system of claim 1, wherein the edges of the thermal interface are coupled to the edges of the cold plate, such that the cavity is formed between the cold plate and the thermal interface.

11. The system of claim 1, wherein the thermally conductive fluid is a thixotropic thermal grease.

12. The system of claim 1, wherein the thermal interface further comprises a thin polymeric layer, and wherein a broad face of the metallic layer is substantially coupled to a broad face of the polymeric layer.

13. The system of claim 12, wherein the polymeric layer comprises polyester and the metallic layer comprises aluminum.

14. The system of claim 1, wherein the thermal interface is joined to the cold plate by adhesive.

15. The system of claim 1, wherein the enclosure houses multiple electronic systems, wherein the cooling system includes a plurality of cold plates and a plurality of electronic system coupling mechanisms, wherein each cold plate is coupled adjacent to an electronic system coupling mechanism within the enclosure.

16. The system of claim 1, wherein the electronic system is coupled to the thermal interface and the cold plate by a pressure plate.

17. The system of claim 16, wherein the pressure plate applies a substantially normal, compressive force along the broad face of the cold plate distal to the electronic system, such that the cold plate applies a compressive force against the thermal interface to thermally couple the thermal interface to the electronic system.

18. The system of claim 17, wherein the pressure plate applies a substantially evenly distributed normal force across the entire broad face of the cold plate.

19. The system of claim 18, wherein the pressure plate further comprises a compliance layer between the pressure plate and the cold plate.

20. The system of claim 19, wherein the compliance layer comprises a foam layer adhered to the broad face of the cold plate proximal the pressure plate.

21. The system of claim 19, wherein the pressure plate additionally forces the thermal interface toward the electronic system.

22. The system of claim 19, wherein the pressure plate is the lid of the electronic system.

23. The system of claim 1, wherein the input manifold includes a throttling hole.

24. A method of manufacturing an electronic system cooling apparatus, the method comprising the steps of:
a) joining a plurality of tubes together along the tube lengths to form a first planar piece, wherein the central axis of the tubes lie in substantially the same plane;
b) slant-cutting an end of the piece, such that the piece end is angled from one longitudinal edge to the other;
c) repeating steps a) and b) to form a second piece;
d) repeating steps a) and b) to form a third piece, wherein step b) is repeated on both ends of the piece to form a first and second angled end, wherein the obtuse angles formed by the angled edges are defined against the same longitudinal edge, and wherein the first angled end is complementary to the angled end of the first piece and the second angled end is complementary to the angled end of the second piece;
e) aligning the broad faces of the first, second, and third pieces within a plane;
f) abutting and joining the angled end of the first piece with the first angled end of the third piece, and the angled end of the second piece with the second angled end of the third piece, such that the each tube of the first and second pieces is fluidly coupled to a tube of the third piece; and,
g) coupling a first and second manifold to the uncut ends of the first and second piece, respectively.

25. The method of claim 24, wherein step a) comprises soldering.

26. The method of claim 25, wherein the tubes and manifolds are pre-tinned.

27. The method of claim 24, wherein step f) comprises the sub-steps of:
applying a soldering paste along the join between the angled ends; and
flowing the paste to form a substantially fluid-impermeable seal.

28. The method of claim 24, wherein step f) comprises the sub-steps of:
joining the angled ends with tape, the tape comprising a first layer of flux-covered solder foil and a second metallic layer, wherein the second metallic layer has a higher melting point than the solder; wherein the tape is applied with the solder side proximal the angled ends; and
flowing the solder to form a substantially fluid-impermeable seal.

29. The method of claim 24, wherein step g) comprises the sub-steps of soldering the first and second manifolds to the first and second pieces, respectively.

30. The method of claim 24, further comprising step h) coupling a thermal interface to the broad face of the joined first, second, and third pieces.

31. The method of claim 29, wherein step h) further comprises coupling the edges of the thermal interface to the edges of the cold plate to form a cavity; and filling the cavity with thermally conductive fluid.

32. A method of manufacturing a cooling system, the method comprising the steps of:
manufacturing a cold plate, comprising the steps of:
carving a plurality of fluidly isolated, thermally coupled, adjacently nested serpentine grooves terminating in a common first end and a common second end into the broad face of a first plate, wherein the common first end is fluidly joined to an outlet manifold and the common second end is fluidly joined to an inlet manifold, wherein the inlet manifold is adjacent to the outlet manifold; and,
soldering a second plate to the carved surface of the first plate, wherein the second plate fluidly seals the grooves to form a plurality of fluidly isolated channels;
joining a thermal interface to the cold plate, comprising the steps of:
joining a first polymeric sheet to a second metallic sheet to form a thermal interface; and,
forming a cavity with the thermal interface and filling the cavity with a thermal grease; and,
coupling the thermal interface to the unbrazed broad face of the second plate;
vertically coupling the cold plate to the interior of the enclosure, such that the broad face is perpendicular to the base of the enclosure.
